(19) United States
(12) Patent Application Publication
(10) Pub. No.: US 2008/0174347 A1
(43) Pub. Date: Jul. 24, 2008

(54) CLOCK SYNCHRONIZATION SYSTEM AND SEMICONDUCTOR INTEGRATED CIRCUIT

(75) Inventor: Yoshinobu OSHIMA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 12/013,515

(22) Filed: Jan. 14, 2008

(30) Foreign Application Priority Data
Jan. 22, 2007 (JP) 2007-011640

(51) Int. Cl. H03L 7/06

(52) U.S. Cl. 327/145; 327/147

(57) ABSTRACT

A clock synchronization system includes a phase-locked loop to generate a multiplied clock based on a reference clock, a frequency divider to generate a plurality of frequency-divided clocks based on the multiplied clock, and a frame pulse generator to generate a frame pulse by frequency-dividing the reference clock, wherein the frequency-divided clocks are phase-locked by the frame pulse.

### BACKGROUND OF THE INVENTION

1. Field of the Invention

The present invention relates to a clock synchronization system and a semiconductor integrated circuit using the same and, particularly, to a clock synchronization system that synchronizes the phases of clocks based on a reference clock and a semiconductor integrated circuit using the same.

2. Description of Related Art

Today's system on chip (SoC) architecture generally includes a plurality of clock domains (which are referred to hereinafter as multi-clock domains) that define the range of a circuit to operate with one clock. Accordingly, the control of clock domain crossing (CDC), which is the transfer of a signal across clock domains, becomes increasingly important.

In order to facilitate the control of CDC, a technique of generating a plurality of synchronous clocks for driving each clock domain based on a reference clock is known. The techniques are described in Japanese Unexamined Patent Application Publication No. 5-136690 (FIGS. 1 and 2) (Araki) and Japanese Unexamined Patent Application Publication No. 2002-108490 (FIGS. 5 and 6) (Nomura et al.). Araki and Nomura et al. disclose that a circuit generates a plurality of synchronous clocks with different frequencies by dividing a reference clock at a different dividing rate.

FIG. 9 shows the clock generator taught by Araki. A frame generator 1 generates a frame clock having a cycle which is a least common multiple of a first dividing rate of a first frequency divider 3 and a second dividing rate of a second frequency divider 4 based on a source clock CLK. The frame generator 1 supplies the frame clock to set terminals S of flip-flops (FFs) 5 and 6. An inverter 2 supplies an inverted signal of the source clock CLK, which is an inverted source clock, to clock terminals C of the FFs 5 and 6. The first frequency divider 3 and the second frequency divider 4 respectively generate a first frequency-divided clock and a second frequency-divided clock based on the source clock CLK. The first frequency divider 3 and the second frequency divider 4 also respectively output a first control clock and a second control clock, which are logical AND of frequency-divided clocks that are generated in the process of frequency division, and supply them to data input terminals D of the FFs 5 and 6. Output terminals Q of the FFs 5 and 6 supply respectively reset signals to the first frequency divider 3 and the second frequency divider 4.

In this configuration, if the first control clock and the second control clock correspond to the rising edge of the frame clock, the clock generator determines that they are in synchronization with each other and does not perform any correction. On the other hand, if the first control clock and the second control clock do not correspond to the rising edge of the frame clock, the clock generator resets the frequency dividers and synchronizes them so that the rising edges correspond to each other.

The clock generator taught by Nomura et al. divides a clock signal CLK according to a count value of a counter which has a least common multiple of the dividing ratios of a plurality of frequency dividers as a maximum value. Thus, frequency-divided clock signals become in-phase each time the clock signal CLK reaches the maximum value. The clock signal CLK with a high frequency is generated by a frequency multiplier which multiplies a reference clock RCK at a prescribed multiplication rate.

Recently, a clock synchronization system which synchronizes the phases of a plurality of clocks based on a reference clock operates at a higher speed with a larger scale.

For example, according to the higher speed and larger scale of SoC having multi-clock domains, a block circuit which constitutes each clock domain now have the speed and scale that are equal to or higher/larger than a conventional LSI chip. As described earlier, it is necessary to synchronize the clocks for driving the multi-clock domains in order to control CDC or the transfer of a signal across clock domains.

For another example, a data transmission system having a serializer/deserializer (SERDES) that mutually converts low-speed parallel data into high-speed serial data is entirely implemented on one SoC chip. A serializer that converts low-speed parallel data into high-speed serial data is generally composed of macros with a large number of channels, which are scattered widespread throughout one chip.

In this example, when converting low-speed parallel data into high-speed serial data, a synchronous clock is required for each macro and channel. As described in PCI-SIG “PCI Express Base specification R1.1”, Mar. 28, 2005, p. 224, Internet: http://www.pcisig.com/members/downloads/specifications/pciexp ress/PCI_Express_Base_{—}11.pdf (Searched on Dec. 21, 2006), there is a specification which synchronizes the delay time from the input of low-speed parallel data to the output of high-speed serial data in a high-speed serial interface specification called PCI-express. Therefore, it is necessary to synchronize the phases of all clocks from high speed to low speed which are used not only between channels (which are referred to as “lanes” in the PCI-express specification) but also between macros. More detailed description is available in “Lane-to-Lane Output Skew” in “4.3.3. Differential Transmitter (Tx) Output Specifications” in the “PCI Express Base specification R1.1”.

However, in the above-described techniques, due to complicated physical phenomenon caused by the large scale, high integration and high density of an LSI chip, issues make it difficult to distribute a “frequency-undivided clock” having a GHz-level frequency all over the LSI chip through a long line.

The issues include electromagnetic coupling between lines (such as coupling due to mutual capacitance and mutual inductance) which are collectively called signal integrity, power supply voltage fluctuation due to power supply line resistance, inductance or capacitance, decrease in yield due to electro-migration or antenna effect and so on. An operating frequency is not determined merely by the degree of a gate delay. Further, the problem is not merely an increase in the proportion of a line delay in a gate delay due to significant line resistance. The problem is that it is difficult to accurately estimate the above-described complicated physical phenomenon at the design stage.

The above-mentioned techniques of Araki and Nomura et al. generate a signal that triggers the synchronization of a plurality of frequency-divided clock, which is the “frame clock” in Araki or the “count value CNT” in Nomura et al., from a “frequency-undivided clock” based on the “source clock CLK” in Araki or the “clock signal CLK” in Nomura et al.

If the techniques of Araki and Nomura et al. are applied to a high-speed and large-scale SoC having the multi-clock domains, there arises a need to distribute a “frequency-undivided clock” over a long distance, which leads to the above issues. If the frequency multiplier 120, the frequency divider 160 and the counter 150 in Nomura et al. are placed adjacently to minimize the line length of a “frequency-undivided clock” and they are allocated to each clock domain for the purpose of avoiding the above issues, even if the frequency multiplier 120 placed in each clock domain generates a multiplied clock based on the same reference clock, it is unable to lock the phases among the clock domains because the counter 150 in each clock domain is independent of each other.

If the techniques of Araki and Nomura et al. are applied to the SERDES macros which are scattered throughout one chip, it presents the state where the frequency multiplier 120, the frequency divider 160 and the counter 150 in Nomura et al. are placed adjacently to minimize the line length of a “frequency-undivided clock” and they are allocated to each SERDES macro, so that it is unable to lock the phases among the SERDES macros because the counter 150 in each SERDES macro is independent of each other.

### SUMMARY

According to one embodiment of the present invention, there is provided a clock synchronization system includes a phase synchronization circuit to generate a multiplied clock based on a reference clock; a frequency divider to generate a plurality of frequency-divided clocks based on the multiplied clock; and a frame pulse generator to generate a frame pulse by frequency-dividing the reference clock, wherein the frequency-divided clocks are phase-locked by the frame pulse.

In the clock synchronization system of this embodiment includes a first phase synchronization circuit to generate a first multiplied clock based on a reference clock; a second phase synchronization circuit to generate a second multiplied clock based on the reference clock; a first frequency divider to generate a first frequency-divided clock based on the first multiplied clock; a second frequency divider to generate a second frequency-divided clock based on the second multiplied clock; and a frame pulse generator to generate a frame pulse by frequency-dividing the reference clock, wherein the first frequency-divided clock and the second frequency-divided clock are phase-locked by the frame pulse.

A case where the clock synchronization system of this embodiment is applied to an LSI chip having a plurality of SERDES macros is as follows. Specifically, a first SERDES macro includes the first phase-locked loop and the first frequency divider and mutually converts low-speed parallel data and high-speed serial data by the first frequency-divided clock, and a second SERDES macro includes the second phase-locked loop and the second frequency divider and mutually converts low-speed parallel data and high-speed serial data by the second frequency-divided clock. In such a case, the first frequency-divided clock and the second frequency-divided clock are phase-locked by the frame pulse, so that synchronization is assured between the high-speed serial data of the first SERDES macro and the high-speed serial data of the second SERDES macro.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram showing the overall configuration of a clock synchronization system according to a first embodiment of the present invention;

FIG. 2 is a timing chart showing the operation of the clock synchronization system according to the first embodiment of the present invention;

FIG. 3 is a circuit diagram showing the overall configuration of a clock synchronization system according to a second embodiment of the present invention;

FIG. 4A is a timing chart showing the operation of the clock synchronization system according to the second embodiment of the present invention;

FIG. 4B is a timing chart showing the operation of the clock synchronization system according to the second embodiment of the present invention;

FIG. 5 is a circuit diagram showing the overall configuration of a clock synchronization system according to a third embodiment of the present invention;

FIG. 6A is a timing chart showing the operation of the clock synchronization system according to the third embodiment of the present invention;

FIG. 6B is a timing chart showing the operation of the clock synchronization system according to the third embodiment of the present invention;

FIG. 7 is a circuit diagram showing the overall configuration of a clock synchronization system according to a fourth embodiment of the present invention;

FIG. 8 is a diagram showing an LSI chip to which a clock synchronization system according to another embodiment of the present invention is applied; and

FIG. 9 is a block diagram showing a clock generator according to a related art.

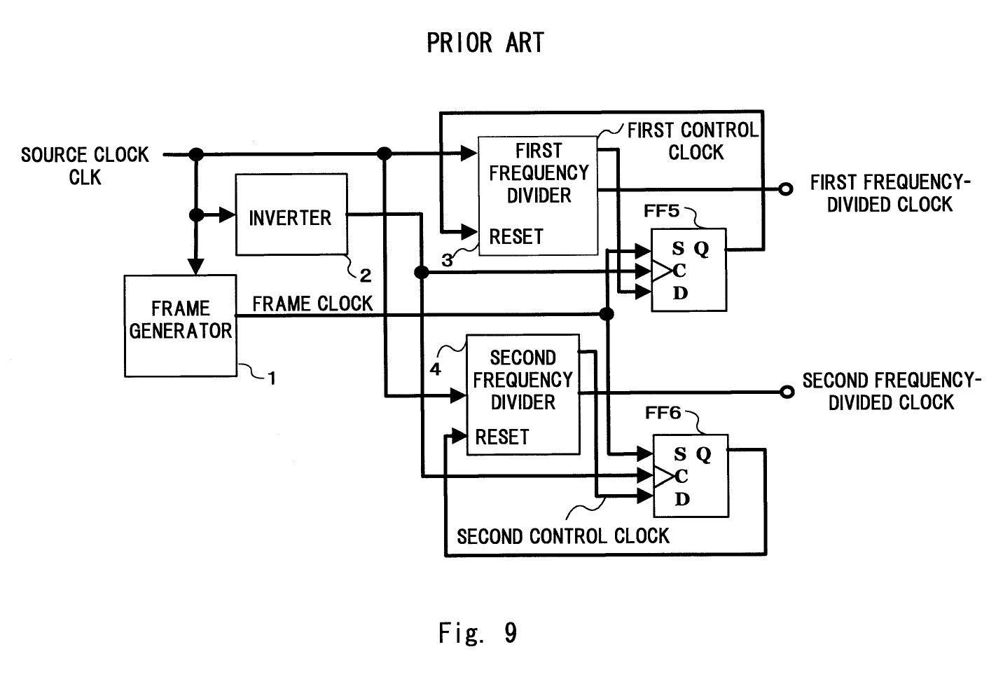

### DETAILED DESCRIPTION OF PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

Exemplary embodiments of the present invention are described hereinafter in detail with reference to the drawings. In the drawings, the same elements are denoted by the same reference symbols, and redundant description is omitted as appropriate to simplify the description.

### First Embodiment

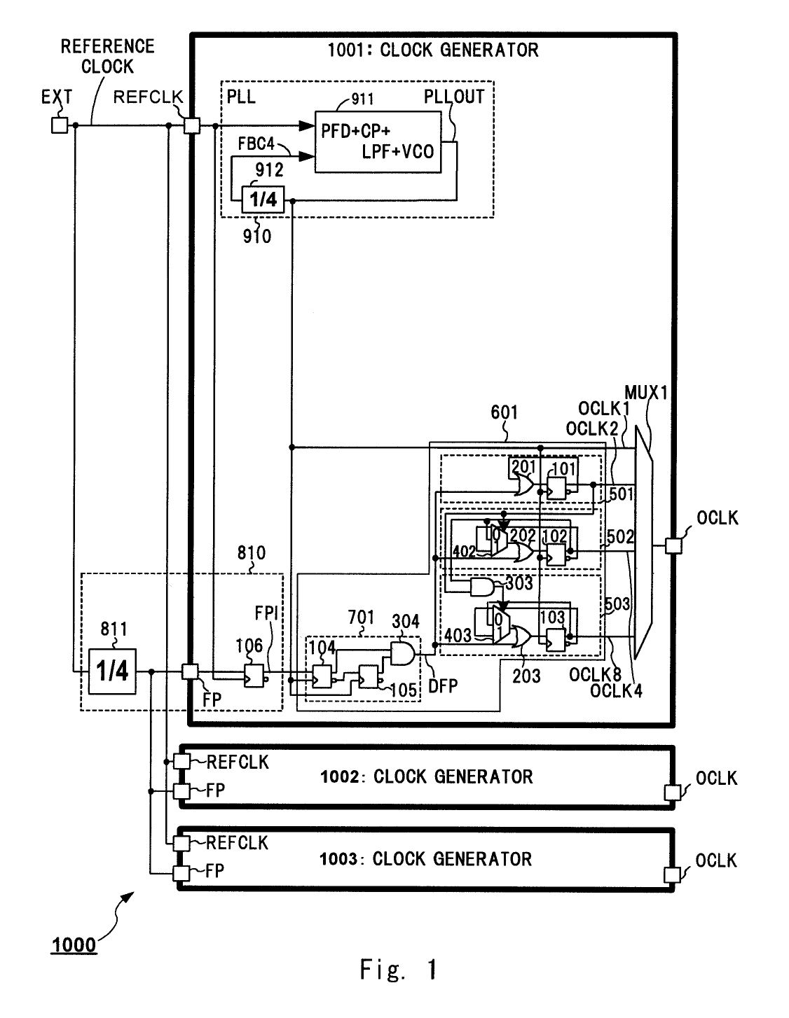

FIG. 1 shows the configuration of a clock synchronization system 1000 according to a first embodiment of the present invention. The clock synchronization system 1000 includes clock generators 1001, 1002 and 1003 having the same configuration. The system has an external terminal EXT to input a reference clock. Each of the clock generators 1001, 1002 and 1003 has a terminal REFCLK to input the reference clock and a terminal FP to input a frame pulse. The reference clock is distributed with an equal delay from the external terminal EXT to each reference clock input terminal REFCLK of the clock generators 1001, 1002 and 1003. A ¼ frequency divider 811 generates a frame pulse based on the reference clock. The ¼ frequency divider 811 distributes the frame pulse with an equal delay from an output terminal to each frame pulse input terminal FP of the clock generators 1001, 1002 and 1003. Each of the clock generators 1001, 1002 and 1003 also has a terminal OCLK to output a synchronous clock, which is described in detail later. Frequency-divided clocks which are output from the synchronous clock output terminals OCLK of the clock generators 1001, 1002 and 1003 are phase-locked with each other.

The configuration of the clock generator 1001 is described hereinafter. A “reference clock” which is referred to in the following description designates a signal having the phase that is immediately after being input to the reference clock input terminal REFCLK unless otherwise noted.

A phase-locked loop (PLL) 910 is a phase synchronizing circuit having a frequency multiplication function. Based on the reference clock, the PLL 910 outputs a PLL output signal PLLOUT which has a quadrupled frequency that multiplies the frequency of the reference clock by 4 and is in-phase with the reference clock. A portion 911 is composed of a phase frequency detector (PFD), a charge pump (CP), a low pass filter (LPF) and a voltage controlled oscillator (VCO). A¼ frequency divider 912 divides the received PLL output signal PLLOUT and outputs a ¼ frequency-divided signal FBC4. The VCO oscillates at a quadrupled frequency based on the reference clock according to a voltage value which is converted from a phase difference between the reference clock and the ¼ frequency-divided signal FBC4 and is stabilized in the phase-locked state.

A flip-flop (FF) 106 performs retiming of a signal having the phase which is immediately after being input to the frame pulse input terminal FP based on the reference clock and outputs a frame pulse FPI. A “frame pulse” which is referred to in the following description designates a frame pulse FPI that is output from the FF 106 unless otherwise noted. The ¼ frequency divider 811 and the FF 106 constitute a frame pulse generator 810.

A frequency divider 601 outputs a plurality of frequency-divided clocks, and it divides the frequency of the PLL output signal PLLOUT according to the frame pulse FPI. Specifically, the frequency divider 601 outputs a 1/1 frequency-divided clock OCLK1, a ½ frequency-divided clock OCLK2, a ¼ frequency-divided clock OCLK4 and a ⅛ frequency-divided clock OCLK8. A selector MUX1 selects an output signal from the frequency-divided clocks OCLK1, OCLK2, OCLK4 and OCLK8 as appropriate and outputs the selected one to the synchronous clock output terminal OCLK.

The configuration of the frequency divider 601 is described in detail below. A synchronous differentiator 701 received the frame pulse FPI and generates a frame pulse differential signal DFP. The frame pulse differential signal DFP is a single-short pulse synchronizing the PLL output signal PLLOUT and having a pulse width as same as one period of the PLL output signal PLLOUT. The synchronous differentiator 701 includes FFs 104 and 105 and an AND circuit 304. The FF 104 receives the frame pulse FPI and the FF 105 receives inverted data output of the FF 104 as data input. The FFs 104 and 105 receive the PLL output signal PLLOUT as a clock input. The AND circuit 304 receives non-inverted data output of the FFs 104 and 105 and outputs the frame pulse differential signal DFP.

A ½ frequency-dividing counter 501, a ¼ frequency-dividing counter 502, and a ⅛ frequency-dividing counter 503 have in common a function to load a default value with the frame pulse differential signal DFP as a load timing.

The ½ frequency-dividing counter 501 includes a FF 101 that receives the PLL output signal PLLOUT as a clock input, and an OR circuit 201 that receives the frame pulse differential signal DFP and inverted data output of the FF 101. The ½ frequency-dividing counter 501 feeds back the output of the OR circuit 201 to generate the ½ frequency-divided clock OCLK2 using a non-inverted data output. The ¼ frequency-dividing counter 502 includes a FF 102 that receives the PLL output signal PLLOUT as a clock input, a selector 402 that selects non-inverted or inverted data output of the FF 102 according to the polarity (“Low” or “High”) of the ½ frequency-divided clock OCLK2, and an OR circuit 202 that receives the frame pulse differential signal DFP and the output of the selector 402. The ¼ frequency-dividing counter 502 feeds back the output of the OR circuit 202 to the data input of the FF 102, thereby obtaining a ¼ frequency-divided clock signal, which is the ¼ frequency-divided clock OCLK4, from the non-inverted data output of the FF 102. The ⅛ frequency-dividing counter 503 includes a FF 103 that receives the PLL output signal PLLOUT as a clock input, a selector 403 that selects non-inverted or inverted data output of the FF 103 according to the polarity (“Low” or “High”) of the output of an AND circuit 303 that receives the ½ frequency-divided clock OCLK2 and the ¼ frequency-divided clock OCLK4 as inputs, and an OR circuit 203 that receives the frame pulse differential signal DFP and the output of the selector 403. The ⅛ frequency-dividing counter 503 feeds back the output of the OR circuit 203 to the data input of the FF 103, thereby obtaining a ⅛ frequency-divided clock signal, which is the ⅛ frequency-divided clock OCLK8, from the non-inverted data output of the FF 103.

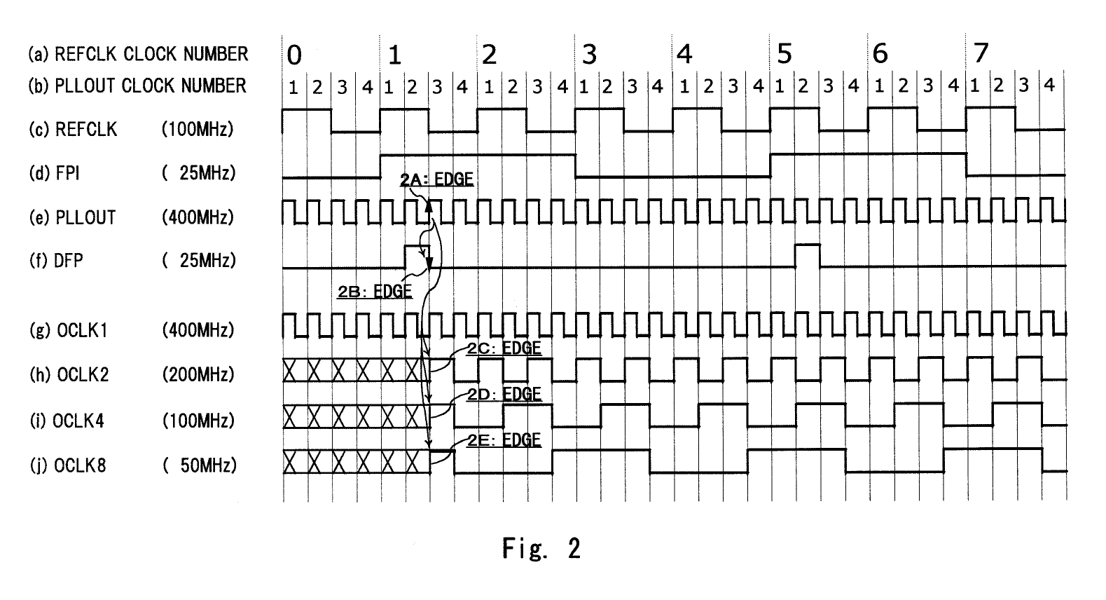

FIG. 2 is a timing chart which shows the operation of the clock generator system 1001 that constitutes the clock synchronization system 1000 of FIG. 1. In FIG. 2, a REFCLK clock number indicates a number which is assigned in ascending order to each cycle of the 100 MHz reference clock that is distributed with an equal delay from the external terminal EXT to each reference clock input terminal REFCLK of the clock generators 1001, 1002 and 1003, which is the clock that is input to the reference clock input terminal REFCLK. A “reference clock” which is referred to in the following description designates a signal having the phase that is immediately after being input to the reference clock input terminal REFCLK unless otherwise noted. A PLLOUT clock number in FIG. 2 indicates a number which is assigned in ascending order to the PLL output signal PLLOUT which has a quadrupled frequency of 400 MHz that multiplies the frequency of the reference clock by 4 and is in-phase with the reference clock. The PLLOUT clock number in FIG. 2 is assigned in units of the cycle of the reference clock of REFCLK, which is the number assigned to the REFCLK clock number in FIG. 2.

In FIG. 2, FPI indicates the frame pulse FPI that is generated as a result of retiming of the 25 MHz frame pulse which is generated by the ¼ frequency divider 811 based on the reference clock that is input from the external terminal EXT and distributed with an equal delay to each frame pulse input terminal FP of the clock generators 1001, 1002 and 1003 based on the reference clock (which is a signal having the phase that is immediately after being input to the reference clock input terminal REFCLK) in the FF 106. A “frame pulse” which is referred to in the following description designates the frame pulse FPI that is output from the FF 106 unless otherwise noted. The multiplication factor of the PLL 910 is 4, the dividing ratio of the ½ frequency-dividing counter 501 is 2, the dividing ratio of the ¼ frequency-dividing counter 502 is 4, the dividing ratio of the ⅛ frequency-dividing counter 503 is 8, and the least common multiple of those values is 8. The ratio of the frame pulse cycle ( 1/25 MHz) to the PLL output signal PLLOUT cycle ( 1/100 MHz) is 16, which is a multiple of the above-mentioned least common multiple of 8.

In FIG. 2, DFP indicates the frame pulse differential signal DFP that is output from the synchronous differentiator 701. In the REFCLK clock number 1 and the PLLOUT clock number 1, the non-inverted and inverted data outputs of the FF 104 are respectively “Low” and “High”, and the non-inverted data output of the FF 105 is “High”, so that the AND circuit 304 outputs “Low”. Next, in the REFCLK clock number 1 and the PLLOUT clock number 2, at the rising edge immediately before the rising edge 2A, the FF 104 fetches “High” of the frame pulse FPI, and the non-inverted and inverted data outputs respectively become “High” and “Low”, so that the AND circuit 304 outputs “High”. Then, in the REFCLK clock number 1 and the PLLOUT clock number 3, at the rising edge 2A, the FF 105 fetches “Low” of the inverted data output of the FF 104 and the non-inverted data output becomes “Low”, so that the output of the AND circuit 304 returns to “Low” to form the falling edge 2B. After that, until the frame pulse FPI becomes “High”, the frame pulse differential signal DFP stays “Low”. In this manner, the frame pulse differential signal DFP is a one-shot pulse which has a pulse width corresponding to one cycle of the PLL output signal PLLOUT.

In FIG. 2, OCLK1, OCLK2, OCLK4 and OCLK8 indicate the 1/1 frequency-divided clock OCLK1, the ½ frequency-divided clock OCLK2, the ¼ frequency-divided clock OCLK4 and the ⅛ frequency-divided clock OCLK8, respectively. The outputs of the OR circuits 201, 202 and 203 are determined according to the signals which are fed back from the FFs 101, 102 and 103, respectively, because the frame pulse differential signal DFP stays “Low” until the REFCLK clock number 1 and the PLLOUT clock number 1. However, the FFs 101, 102 and 103 are in the indeterminate state until the REFCLK clock number 1 and the PLLOUT clock number 2.

On the other hand, in the REFCLK clock number 1 and the PLLOUT clock number 2 in FIG. 2, the outputs of the OR circuits 201, 202 and 203, which are the data inputs to the FFs 101, 102 and 103, respectively, are forcibly fixed to “High” because the frame pulse differential signal DFP is “High”. Further, at the next rising edge 2A, the FFs 101, 102 and 103 fetch (load) the previous data inputs at “High”. Thus, the FFs 101, 102 and 103 are initialized to the set state for the first time at this timing, so that the ½ frequency-divided clock OCLK2, the ¼ frequency-divided clock OCLK4 and the ⅛ frequency-divided clock OCLK8 become the determinate state at “High” from the indeterminate state.

After that, at the falling edge 2B, the frame pulse differential signal DFP returns to “Low”, and thereby the outputs of the OR circuits 201, 202 and 203 return to the state where they are determined according to the signals which are fed back from the FFs 101, 102 and 103, respectively, which is the state that allows the frequency division.

Because the dividing ratio of the ½ frequency-dividing counter 501 is 2, the dividing ratio of the ¼ frequency-dividing counter 502 is 4, the dividing ratio of the ⅛ frequency-dividing counter 503 is 8, and the least common multiple of those values is 8, the determinate state where all of the ½ frequency-divided clock OCLK2, the ¼ frequency-divided clock OCLK4 and the ⅛ frequency-divided clock OCLK8 are “High” (the rising edges 2C, 2D and 2E) is brought about every 8 cycles of the PLL output signal PLLOUT. Specifically, it occurs first time in the REFCLK clock number 1 and the PLLOUT clock number 3, then in the REFCLK clock number 3 and the PLLOUT clock number 3, and further in the REFCLK clock number 5 and the PLLOUT clock number 3.

On the other hand, the frame pulse FPI and the frame pulse differential signal DFP appear at the cycle of 16, which is a multiple of the above-described least common multiple 8, which is specifically in the REFCLK clock number 1 and the PLLOUT clock number 3, then in the REFCLK clock number 5 and the PLLOUT clock number 3, thereby allowing a series of the above-described synchronization processing. Because the procedure of the series of synchronization processing and the frequency-dividing operation are always triggered only by the rising edge of the PLL output signal PLLOUT, a duty cycle of 50% in each frequency-divided clock is assured.

Beginning at the determinate state where all of the ½ frequency-divided clock OCLK2, the ¼ frequency-divided clock OCLK4 and the ⅛ frequency-divided clock OCLK8 are “High”, the FFs 101, 102 and 103 restart the frequency-dividing operation. Further, triggered by the rising edge of the PLL output signal PLLOUT, the rising or falling edges of the ½ frequency-divided clock OCLK2, the ¼ frequency-divided clock OCLK4 and the ⅛ frequency-divided clock OCLK8 are determined by each delay of the FFs 101, 102 and 103. In other words, the frequency-divided clocks have the relationship in which the signal transitions are mutually determined. This state is referred to that the frequency-divided clocks are in-phase or phase-locked with each other. If the delays of the FFs 101, 102 and 103 are equal, they have a zero skew. Although the above-described determinate initial state which triggers the restart of the frequency-dividing operation is the state where the ½ frequency-divided clock OCLK2, the ¼ frequency-divided clock OCLK4 and the ⅛ frequency-divided clock OCLK8 are “High” in the first embodiment, it is not necessary that all of those clocks are “High” as long as the state where the frequency-divided clocks which are predictable based on the circuit configuration of the first embodiment are mutually determinate.

Further, as described earlier, because the reference clock which is input to the external terminal EXT is distributed in common to the clock generators 1001, 1002 and 1003 and the frame pulse which is generated by the ¼ frequency divider 811 is also distributed in common to the clock generators 1001, 1002 and 1003, the frequency-divided clocks which are generated by the clock generators 1001, 1002 and 1003 are also phase-locked with each other.

Furthermore, if the clock generators 1001, 1002 and 1003 are designed to have the same configuration including a signal line delay and the reference clock which is input to the external terminal EXT and the frame pulse which is generated by the ¼ frequency divider 811 are distributed with an equal delay to the clock generators 1001, 1002 and 1003, the ½ frequency-divided clock OCLK2, the ¼ frequency-divided clock OCLK4 and the ⅛ frequency-divided clock OCLK8 which are generated by the clock generators 1001, 1002 and 1003 having a zero skew can be obtained, in addition to that the frequency-divided clocks which are generated by the clock generators 1001, 1002 and 1003 are phase-locked with each other.

An overall configuration when the clock synchronization system 1000 is applied to a large-scale, high-integration, high-density LSI chip is described hereinafter. As described earlier, the clock generators 1001, 1002 and 1003 have the same function, and the PLL output signal PLLOUT and the 1/1 frequency-divided clock OCLK1, the ½ frequency-divided clock OCLK2, the ¼ frequency-divided clock OCLK4 and the ⅛ frequency-divided clock OCLK8 which are generated therein are phase-locked with each other (in the relationship of the clock generators 1001, 1002 and 1003). Thus, when distributing the frequency-undivided clock (the PLL output signal PLLOUT) with a high frequency or the frequency-divided clock (the 1/1 frequency-divided clock OCLK1, the ½ frequency-divided clock OCLK2, the ¼ frequency-divided clock OCLK4 and the ⅛ frequency-divided clock OCLK8) throughout the LSI chip, a prescribed dividable range for assuring the signal integrity and a prescribed distributable line length on the LSI chip are specified. Then, according to the specified range area and the line length on the LSI chip, the clock generators 1001, 1002 and 1003 are allocated. If the number of the specified range areas on the LSI chip is four or more, a clock generator 1004 or the like is added.

The reference clock that is input to the external terminal EXT and the frame pulse that is generated by the ¼ frequency divider 811 which are distributed in common to the clock generators 1001, 1002 and 1003 have a lower frequency than the frequency-undivided clock having the high frequency. Therefore, when the clock synchronization system 1000 is applied to a large-scale, high-integration, high-density LSI chip, even if the reference clock and the frame pulse are distributed all over the LSI chip through a long distance line, the signal integrity of those signals is still assured. A specific example is described later.

The PLL 910 which has a frequency multiplication function can set an arbitrary multiplication factor including a fractional multiplication factor. The PLL 910 may have a function to vary a multiplication factor, in which case there may be a function to vary the cycle of a frame pulse which is generated by the frame pulse generator according to the variable multiplication factor. A PLL frequency synthesizer or the like may be used as a PLL with a variable multiplication factor. Although the ½ frequency-dividing counter 501, the ¼ frequency-dividing counter 502 and the ⅛ frequency-dividing counter 503 are shown as examples in this embodiment, an arbitrary multiplication factor including a fractional multiplication factor may be set, and the number of frequency dividers is unlimited. Further, there may be a function to vary a dividing ratio, in which case there may also be a function to vary the cycle of a frame pulse which is generated by the frame pulse generator according to the variable dividing ratio. Although the frequency-divided clocks OCLK1, OCLK2, OCLK4 and OCLK8 are selectively output from the selector MUX1 as appropriate in this embodiment, all those clocks may be output in parallel.

### Second Embodiment

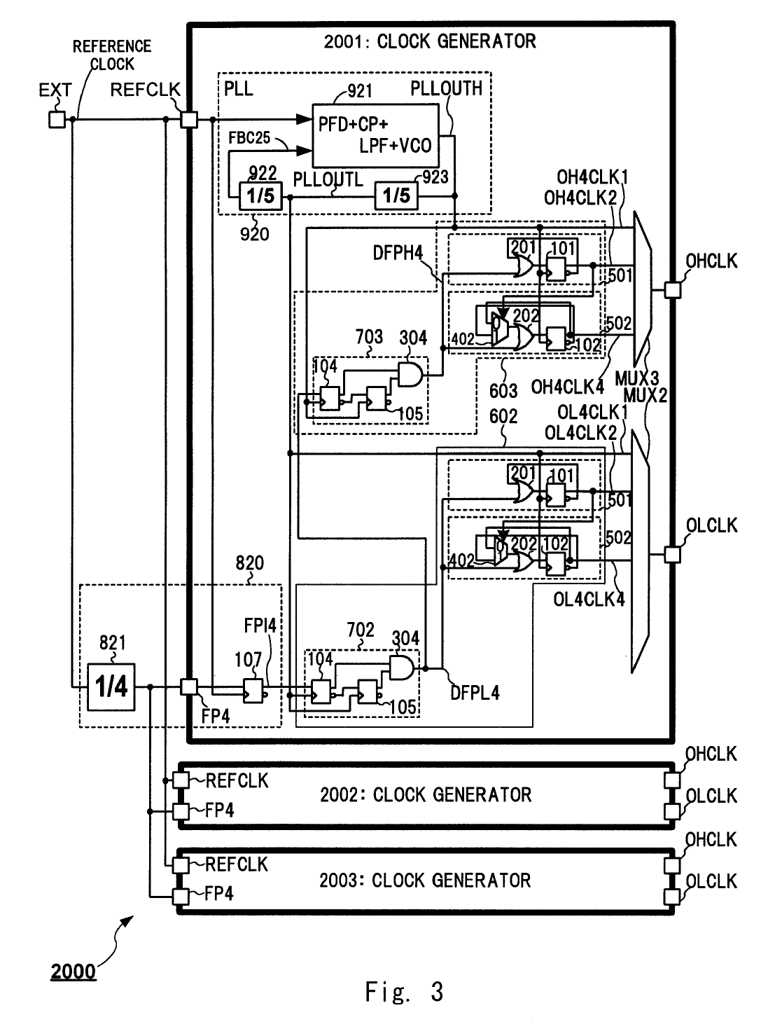

FIG. 3 shows a clock synchronization system 2000 according to a second embodiment of the present invention. The clock synchronization system 2000 includes clock generators 2001, 2002 and 2003 having the same configuration. The system has an external terminal EXT to input a reference clock. Each of the clock generators 2001, 2002 and 2003 has a terminal REFCLK to input the reference clock, a terminal FP4 to input a frame pulse, and terminals OHCLK and OLCLK to output synchronous clocks. A ¼ frequency divider 821 generates a frame pulse based on a reference clock.

The configuration of the clock generator 2001 is described hereinafter. A “reference clock” which is referred to in the following description designates a signal having the phase that is immediately after being input to the reference clock input terminal REFCLK unless otherwise noted.

A phase-locked loop (PLL) 920 is a phase synchronizing circuit having a frequency multiplication function. Based on the reference clock, the PLL 920 outputs a high-speed PLL output signal PLLOUTH which has a frequency that multiplies the frequency of the reference clock by 25 and is in-phase with the reference clock. A portion 921 has the same configuration as the portion 911 shown in FIG. 1. A ⅕ frequency divider 923 receives the high-speed PLL output signal PLLOUTH as an input and outputs a low-speed PLL output signal PLLOUTL, which is a ⅕ frequency-divided signal of the high-speed PLL output signal PLLOUTH. Then, al/5 frequency divider 922 receives the low-speed PLL output signal PLLOUTL as an input and outputs a signal FBC25, which is ⅕ frequency-divided signal of the low-speed PLL output signal PLLOUTL and is thus 1/25 frequency-divided signal of the high-speed PLL output signal PLLOUTH. A VCO in the portion 921 oscillates at a frequency that multiplies the reference clock by 25 according to a voltage value which is converted from a phase difference between the reference clock and the 1/25 frequency-divided signal FBC5 and is stabilized in the phase-locked state.

A flip-flop (FF) 107 has the same function as the FF 106 shown in FIG. 1. The FF 107 performs retiming of a signal having the phase which is immediately after being input to the frame pulse input terminal FP4 based on the reference clock and outputs a frame pulse FPI4. The ¼ frequency divider 821 and the FF 107 constitute a frame pulse generator 820.

A frequency divider 602 outputs a plurality of frequency-divided clocks, and it divides the frequency of the low-speed PLL output signal PLLOUTL according to the frame pulse FPI4. Specifically, the frequency divider 602 outputs a 1/1 frequency-divided clock OL4CLK1, a ½ frequency-divided clock OL4CLK2, and a ¼ frequency-divided clock OL4CLK4. A selector MUX2 makes a selection from the frequency-divided clocks OL4CLK1, OL4CLK2 and OL4CLK4 as appropriate and outputs the selected one to the synchronous clock output terminal OLCLK.

The configuration of the frequency divider 602 is described in detail below. A synchronous differentiator 702 receives the frame pulse FPI4 and generates a frame pulse differential signal DFPL4, which is a one-shot pulse that is in-phase with the low-speed PLL output signal PLLOUTL and has a pulse width corresponding to one cycle of the low-speed PLL output signal PLLOUTL. The synchronous differentiator 702 has the same function as the synchronous differentiator 701 shown in FIG. 1.

A ½ frequency-dividing counter 501 and a ¼ frequency-dividing counter 502 in the frequency divider 602 have in common a function to load a default value with the frame pulse differential signal DFPL4 as a load timing. The ½ frequency-dividing counter 501 and the ¼ frequency-dividing counter 502 have the same function as the ½ frequency-dividing counter 501 and the ¼ frequency-dividing counter 502 which constitute the frequency divider 601 shown in FIG. 1, and they output the ½ frequency-divided clock OL4CLK2 and the ¼ frequency-divided clock OL4CLK4, respectively.

A frequency divider 603 also outputs a plurality of frequency-divided clocks, and it divides the frequency of the high-speed PLL output signal PLLOUTH according to the frame pulse differential signal DFPL4. Specifically, the frequency divider 603 outputs a 1/1 frequency-divided clock OH4CLK1, a ½ frequency-divided clock OH4CLK2, and a ¼ frequency-divided clock OH4CLK4. A selector MUX3 makes a selection from the frequency-divided clocks OH4CLK1, OH4CLK2 and OH4CLK4 as appropriate and outputs the selected one to the synchronous clock output terminal OHCLK.

The configuration of the frequency divider 603 is described in detail below. A synchronous differentiator 703 receives the frame pulse differential signal DFPL4 and generates a frame pulse differential signal DFPH4, which is a one-shot pulse that is in-phase with the high-speed PLL output signal PLLOUTH and has a pulse width corresponding to one cycle of the high-speed PLL output signal PLLOUTH. The synchronous differentiator 703 has the same function as the synchronous differentiator 701 shown in FIG. 1.

A ½ frequency-dividing counter 501 and a ¼ frequency-dividing counter 502 in the frequency divider 603 have in common a function to load a default value with the frame pulse differential signal DFPH4 as a load timing. The ½ frequency-dividing counter 501 and the ¼ frequency-dividing counter 502 have the same function as the ½ frequency-dividing counter 501 and the ¼ frequency-dividing counter 502 which constitute the frequency divider 601 shown in FIG. 1, and they output the ½ frequency-divided clock OH4CLK2 and the ¼ frequency-divided clock OH4CLK4, respectively.

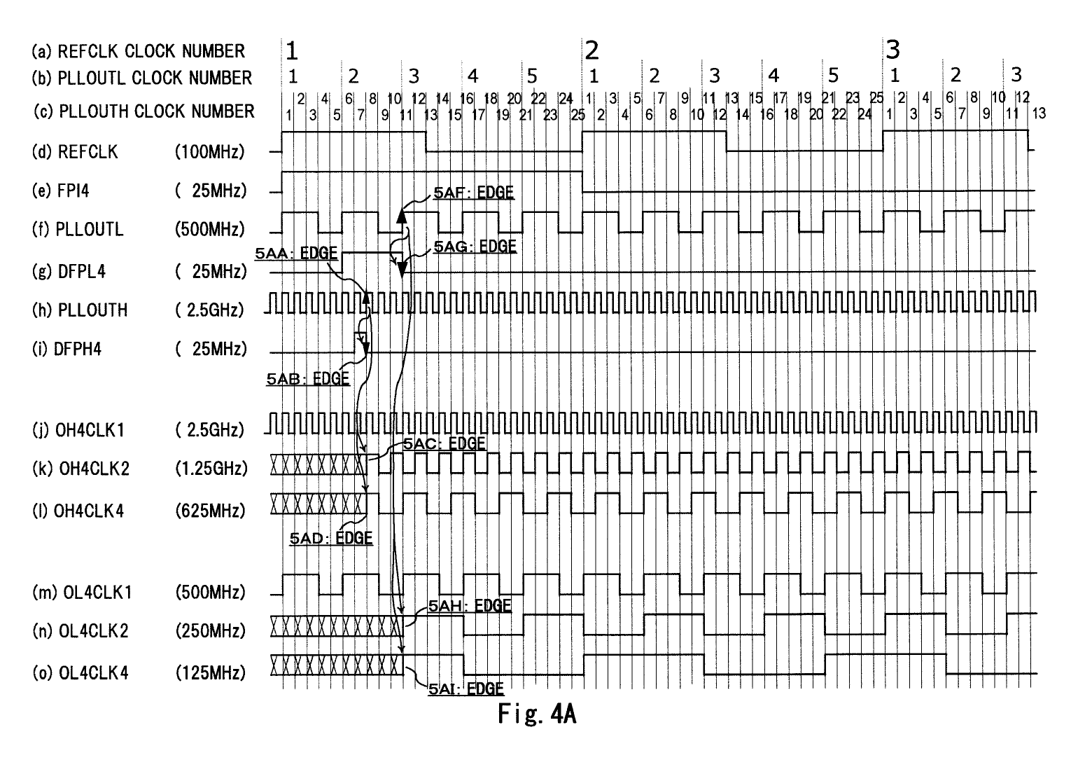

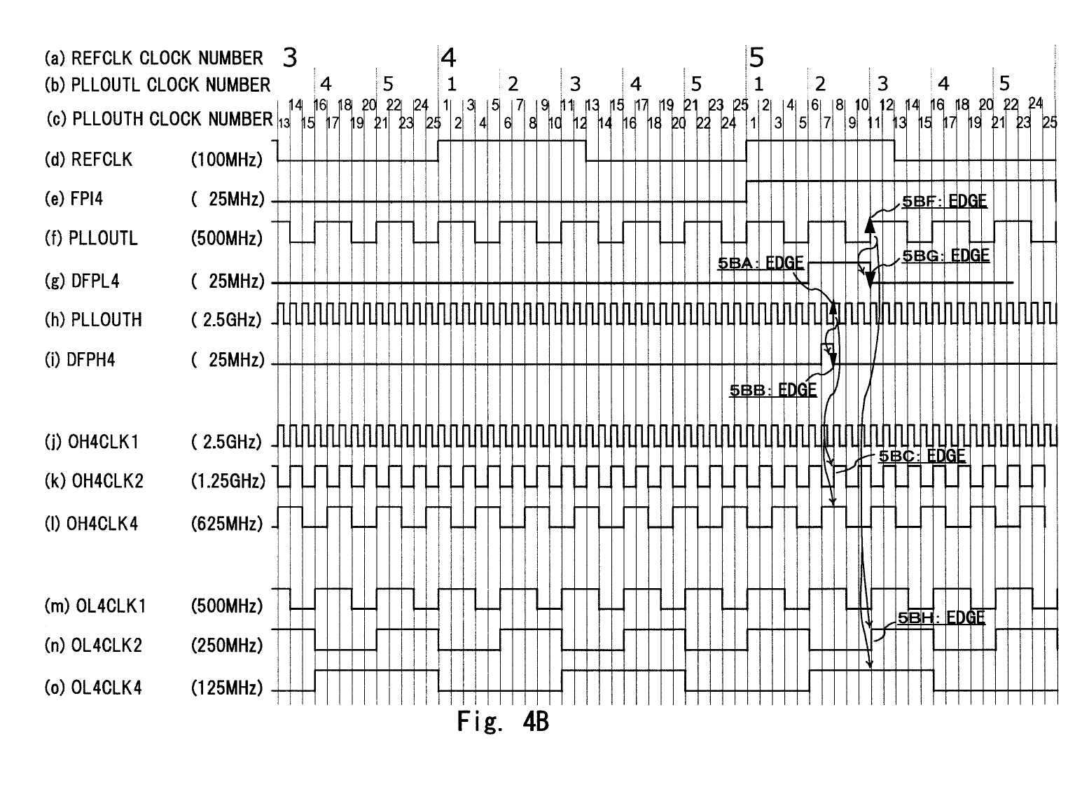

FIGS. 4A and 4B are timing charts which show the operation of the clock generator 2001 that constitutes the clock synchronization system 2000 of FIG. 3. A REFCLK clock number in FIGS. 4A and 4B indicates a number which is assigned in ascending order to each cycle of the 100 MHz reference clock that is distributed from the external terminal EXT to each reference clock input terminal REFCLK of the clock generators 2001, 2002 and 2003, which is the clock that is input to the reference clock input terminal REFCLK as shown in FIGS. 4A and 4B.

A “reference clock” which is referred to in the following description designates a signal having the phase that is immediately after being input to the reference clock input terminal REFCLK unless otherwise noted. A PLLOUTL clock number in FIGS. 4A and 4B indicates a number which is assigned in ascending order to the low-speed PLL output signal PLLOUTL which has a frequency of 500 MHz that divides the frequency of the high-speed PLL output signal PLLOUTH by 5 and is in-phase with the high-speed PLL output signal PLLOUTH. The PLLOUT clock number is assigned in units of the cycle of the reference clock of REFCLK in FIGS. 4A and 4B, which is the number assigned to the REFCLK clock number in FIGS. 4A and 4B.

A PLLOUTH clock number in FIGS. 4A and 4B indicates a number which is assigned in ascending order to the high-speed PLL output signal PLLOUTH which has a frequency of 2.5 GHz that multiplies the frequency of the reference clock by 25 and is in-phase with the reference clock. The PLLOUTH clock number is assigned in units of the cycle of the reference clock of REFCLK in FIGS. 4A and 4B, which is the number assigned to the REFCLK clock number in FIGS. 4A and 4B. The timing charts of FIGS. 4A and 4B are chronologically successive, and the signals shown therein are common between FIGS. 4A and 4B.

In FIGS. 4A and 4B, FPI4 indicates the frame pulse FPI4 that is generated as a result of retiming of the 25 MHz frame pulse which is generated by the ¼ frequency divider 821 based on the reference clock that is input from the external terminal EXT and distributed to each frame pulse input terminal FP4 of the clock generators 2001, 2002 and 2003 based on the reference clock (which is a signal having the phase that is immediately after being input to the reference clock input terminal REFCLK) in the FF 107.

The multiplication factor of the PLL 920 that generates the low-speed PLL output signal PLLOUTL is 5, the dividing ratio of the ½ frequency-dividing counter 501 in the frequency divider 602 that divides the low-speed PLL output signal PLLOUTL is 2, the dividing ratio of the ¼ frequency-dividing counter 502 therein is 4, and the least common multiple of those values is 20. The ratio of the frame pulse FPI4 cycle ( 1/25 MHz) to the low-speed PLL output signal PLLOUTL cycle ( 1/500 MHz) is 20, which is the same as the above-mentioned least common multiple of 20.

The multiplication factor of the PLL 920 that generates the high-speed PLL output signal PLLOUTH is 25, the dividing ratio of the ½ frequency-dividing counter 501 in the frequency divider 603 that divides the high-speed PLL output signal PLLOUTH is 2, the dividing ratio of the ¼ frequency-dividing counter 502 therein is 4, and the least common multiple of those values is 100. The ratio of the frame pulse FPI4 cycle ( 1/25 MHz) to the high-speed PLL output signal PLLOUTH cycle ( 1/2.5 GHz) is 100, which is the same as the above-mentioned least common multiple of 100.

In FIGS. 4A and 4B, DFPL4 indicates the frame pulse differential signal DFPL4 that is output from the synchronous differentiator 702. As a result of synchronous differentiation of the frame pulse FPI4 based on the low-speed PLL output signal PLLOUTL, there is generated the frame pulse differential signal DFPL4, which is a one-shot pulse that has a pulse width corresponding to one cycle of the low-speed PLL output signal PLLOUTL. In FIGS. 4A and 4B, DFPH4 indicates the frame pulse differential signal DFPH4 that is output from the synchronous differentiator 703. As a result of synchronous differentiation of the frame pulse differential signal DFPL4 based on the high-speed PLL output signal PLLOUTH, there is generated the frame pulse differential signal DFPH4, which is a one-shot pulse that has a pulse width corresponding to one cycle of the high-speed PLL output signal PLLOUTH.

In FIGS. 4A and 4B, OL4CLK1, OL4CLK2 and OL4CLK4 indicate the 1/1 frequency-divided clock OL4CLK1, the ½ frequency-divided clock OL4CLK2 and the ¼ frequency-divided clock OL4CLK4, respectively, based on the low-speed PLL output signal PLLOUTL. Because the dividing ratio of the ½ frequency-dividing counter 501 in the frequency divider 602 is 2, the dividing ratio of the ¼ frequency-dividing counter 502 therein is 4, and the least common multiple of those values is 4, the determinate state where all of the ½ frequency-divided clock OL4CLK2 and the ¼ frequency-divided clock OL4CLK4 are “High” (the rising edges 5AH and 5AI) is brought about every 4 cycles of the low-speed PLL output signal PLLOUTL and every 20 cycles of the high-speed PLL output signal PLLOUTH.

Specifically, it occurs first time in the REFCLK clock number 1 and the PLLOUTL clock number 3 in FIG. 4A, then in the REFCLK clock number 2 and the PLLOUTL clock number 2, and further in the REFCLK clock number 3 and the PLLOUTL clock number 1. On the other hand, the frame pulse FPI4 and the frame pulse differential signal DFPL4 appear at the cycle of 20 (based on the cycle of the low-speed PLL output signal PLLOUTL) or at the cycle of 100 (based on the cycle of the high-speed PLL output signal PLLOUTH), which is a multiple of the above-described least common multiple 4. Specifically, it occurs first time in the REFCLK clock number 1 and the PLLOUTL clock number 3 or the PLLOUTH clock number 11 in FIG. 4A, then in the REFCLK clock number 5 and the PLLOUTL clock number 3 or the PLLOUTH clock number 11 in FIG. 4B, thereby allowing a series of the above-described synchronization processing. Because the procedure of the series of synchronization processing and the frequency-dividing operation are always triggered only by the rising edge of the low-speed PLL output signal PLLOUTL, a duty cycle of 50% in each frequency-divided clock is assured.

In FIGS. 4A and 4B, OH4CLK1, OH4CLK2 and OH4CLK4 indicate the 1/1 frequency-divided clock OH4CLK1, the ½ frequency-divided clock OH4CLK2 and the ¼ frequency-divided clock OH4CLK4, respectively, based on the high-speed PLL output signal PLLOUTH. Because the dividing ratio of the ½ frequency-dividing counter 501 in the frequency divider 603 is 2, the dividing ratio of the ¼ frequency-dividing counter 502 there in is 4, and the least common multiple of those values is 4, the determinate state where all of the ½ frequency-divided clock OH4CLK2 and the ¼ frequency-divided clock OH4CLK4 are “High” (the rising edges 5AC and 5AD) is brought about every 4 cycles of the high-speed PLL output signal PLLOUTH. Specifically, it occurs first time in the REFCLK clock number 1 and the PLLOUTH clock number 8 in FIG. 4A, then in the REFCLK clock number 1 and the PLLOUTH clock number 12, and further in the REFCLK clock number 1 and the PLLOUTH clock number 16. On the other hand, the frame pulse FPI4 and the frame pulse differential signal DFPH4 appear at the cycle of 100 (based on the cycle of the high-speed PLL output signal PLLOUTH), which is a multiple of the above-described least common multiple 4. Specifically, it occurs first time in the REFCLK clock number 1 and the PLLOUTH clock number 8 in FIG. 4A, then in the REFCLK clock number 5 and the PLLOUTH clock number 8 in FIG. 4B, thereby allowing a series of the above-described synchronization processing. Because the procedure of the series of synchronization processing and the frequency-dividing operation are always triggered only by the rising edge of the high-speed PLL output signal PLLOUTH, a duty cycle of 50% in each frequency-divided clock is assured.

### Third Embodiment

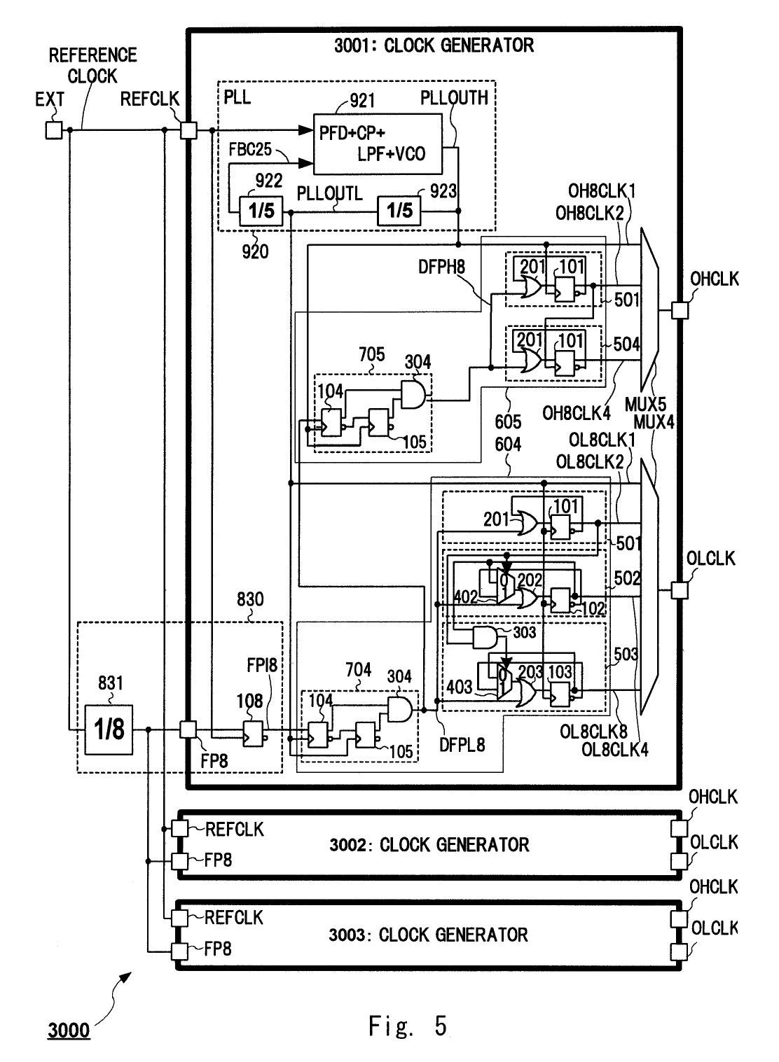

FIG. 5 shows a clock synchronization system 3000 according to a third embodiment of the present invention. The clock synchronization system 3000 includes clock generators 3001, 3002 and 3003 having the same configuration. The system has an external terminal EXT to input a reference clock. Each of the clock generators 3001, 3002 and 3003 has a terminal REFCLK to input the reference clock, a terminal FP8 to input a frame pulse, and terminals OHCLK and OLCLK to output synchronous clocks. A ⅛ frequency divider 831 generates a frame pulse based on a reference clock.

The configuration of the clock generator 3001 is described hereinafter. A “reference clock” which is referred to in the following description designates a signal having the phase that is immediately after being input to the reference clock input terminal REFCLK unless otherwise noted.

A phase-locked loop (PLL) 920 which constitutes the clock generator 3001 has a frequency multiplication function, and it has the same function as the PLL 920 which constitutes the clock generator 2001 shown in FIG. 3. The same reference numerals are used for the same elements.

A FF 108 has the same function as the FF 106 shown in FIG. 1, and it performs retiming of a signal having the phase which is immediately after being input to the frame pulse input terminal FP14 based on the reference clock and outputs a frame pulse FPI8. The ⅛ frequency divider 831 and the FF 108 constitute a frame pulse generator 830.

A frequency divider 604 outputs a plurality of frequency-divided clocks, and it divides the frequency of the low-speed PLL output signal PLLOUTL according to the frame pulse FPI8. Specifically, the frequency divider 604 outputs a 1/1 frequency-divided clock OL8CLK1, a ½ frequency-divided clock OL8CLK2, a ¼ frequency-divided clock OL8CLK4 and a ⅛ frequency-divided clock OL8CLK8. A selector MUX4 makes a selection from the frequency-divided clocks OL8CLK1, OL8CLK2, OL8CLK4 and OL8CLK8 as appropriate and outputs the selected one to the synchronous clock output terminal OLCLK.

The configuration of the frequency divider 604 is described in detail below. A synchronous differentiator 704 receives the frame pulse FPI8 and generates a frame pulse differential signal DFPL8, which is a one-shot pulse that is in-phase with the low-speed PLL output signal PLLOUTL and has a pulse width corresponding to one cycle of the low-speed PLL output signal PLLOUTL. The synchronous differentiator 704 has the same function as the synchronous differentiator 701 shown in FIG. 1.

A ½ frequency-dividing counter 501, a ¼ frequency-dividing counter 502 and a ⅛ frequency-dividing counter 503 in the frequency divider 604 have in common a function to load a default value with the frame pulse differential signal DFPL8 as a load timing. The ½ frequency-dividing counter 501, the ¼ frequency-dividing counter 502 and the ⅛ frequency-dividing counter 503 have the same function as the ½ frequency-dividing counter 501, the ¼ frequency-dividing counter 502 and the ⅛ frequency-dividing counter 503 which constitute the frequency divider 601 shown in FIG. 1, and they output the ½ frequency-divided clock OL8CLK2, the ¼ frequency-divided clock OL8CLK4, and the ⅛ frequency-divided clock OL8CLK8, respectively.

A frequency divider 605 also outputs a plurality of frequency-divided clocks, and it divides the frequency of the high-speed PLL output signal PLLOUTH according to the frame pulse differential signal DFPL8. Specifically, the frequency divider 605 outputs a 1/1 frequency-divided clock OH8CLK1, a ½ frequency-divided clock OH8CLK2, and a ¼ frequency-divided clock OH8CLK4. A selector MUX5 makes a selection from the frequency-divided clocks OH8CLK1, OH8CLK2 and OH8CLK4 as appropriate and outputs the selected one to the synchronous clock output terminal OHCLK.

The configuration of the frequency divider 605 is described in detail below. A synchronous differentiator 705 receives the frame pulse differential signal DFPL8 and generates a frame pulse differential signal DFPH8. The frame pulse differential signal is a one-shot pulse that is in-phase with the high-speed PLL output signal PLLOUTH and has a pulse width corresponding to one cycle of the high-speed PLL output signal PLLOUTH. The synchronous differentiator 705 has the same function as the synchronous differentiator 701 shown in FIG. 1.

A ½ frequency-dividing counter 501 and a ¼ frequency-dividing counter 504 in the frequency divider 605 have in common a function to load a default value with the frame pulse differential signal DFPH8 as a load timing. The ½ frequency-dividing counter 501 has the same function as the ½ frequency-dividing counter 501 which constitutes the frequency divider 601 shown in FIG. 1, and it outputs the ½ frequency-divided clock OH8CLK2. On the other hand, although the ¼ frequency-dividing counter 504 has the same circuit configuration as the ½ frequency-dividing counter 501, the relationship of input and output signals is different. Specifically, the ¼ frequency-dividing counter 504 includes the FF 101 that receives as a clock input the ½ frequency-divided clock OH8CLK2, which is the output of the ½ frequency-dividing counter 501 in the previous stage, and the OR circuit 201 that receives as inputs the frame pulse differential signal DFPH8 and the inverted data output of the FF 101. The ¼ frequency-dividing counter 504 feeds back the output of the OR circuit 201 to the data input of the FF 101, thereby obtaining the ¼ frequency-divided clock OH8CLK4 from the non-inverted data output of the FF 101.

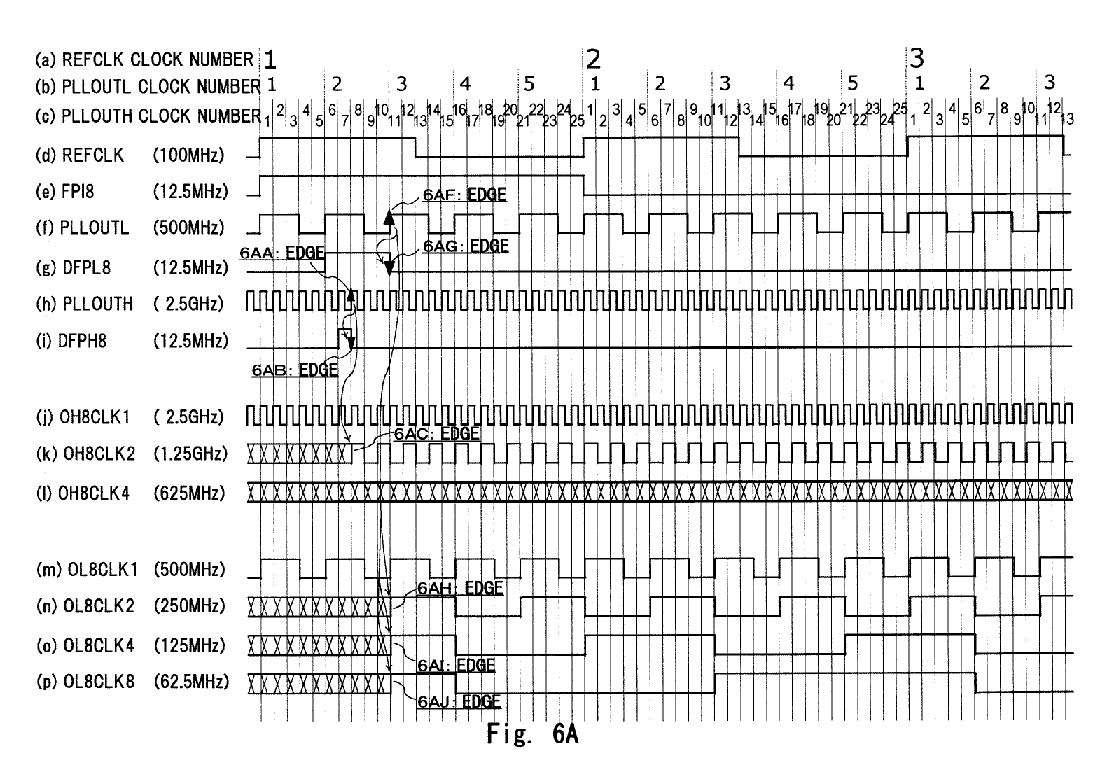

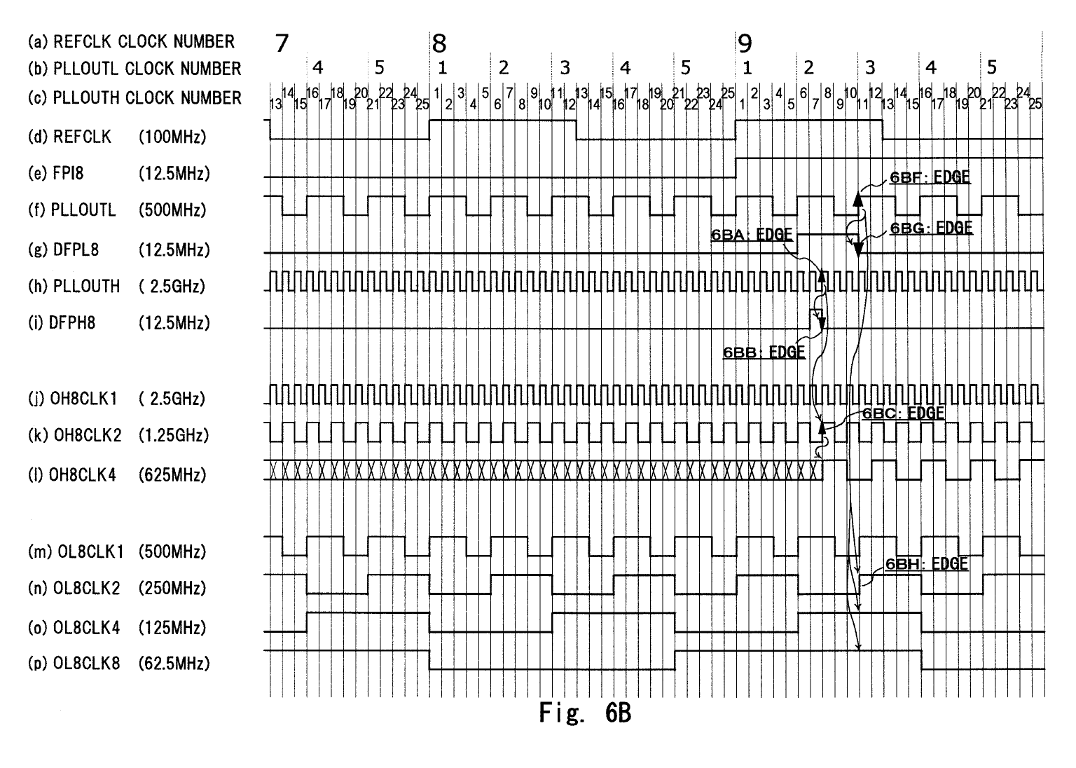

FIGS. 6A and 6B are timing charts which show the operation of the clock generator 3001 that constitutes the clock synchronization system 3000 of FIG. 5. A REFCLK clock number in FIGS. 6A and 6B indicates a number which is assigned in ascending order to each cycle of the 100 MHz reference clock that is distributed from the external terminal EXT to each reference clock input terminal REFCLK of the clock generators 3001, 3002 and 3003, which is the clock that is input to the reference clock input terminal REFCLK as shown in FIGS. 6A and 6B.

A “reference clock” which is referred to in the following description designates a signal having the phase that is immediately after being input to the reference clock input terminal REFCLK unless otherwise noted. A PLLOUTL clock number in FIGS. 6A and 6B indicates a number which is assigned in ascending order to the low-speed PLL output signal PLLOUTL which has a frequency of 500 MHz that divides the frequency of the high-speed PLL output signal PLLOUTH by 5 and is in-phase with the high-speed PLL output signal PLLOUTH. The PLLOUT clock number is assigned in units of the cycle of the reference clock of REFCLK in FIGS. 6A and 6B, which is the number assigned to the REFCLK clock number in FIGS. 6A and 6B. A PLLOUTH clock number in FIGS. 6A and 6B indicates a number which is assigned in ascending order to the high-speed PLL output signal PLLOUTH which has a frequency of 2.5 GHz that multiplies the frequency of the reference clock by 25 and is in-phase with the reference clock. The PLLOUTH clock number is assigned in units of the cycle of the reference clock of REFCLK in FIGS. 6A and 6B, which is the number assigned to the REFCLK clock number in FIGS. 6A and 6B.

The timing charts of FIGS. 6A and 6B are chronologically successive, and the signals shown therein are common between FIGS. 6A and 6B. However, the timing chart from the REFCLK clock number 3 and the PLLOUTH clock number 13 in FIG. 6A to the REFCLK clock number 7 and the PLLOUTH clock number 13 in FIG. 6B is omitted.

In FIGS. 6A and 6B, FPI8 indicates the frame pulse FPI8 that is generated as a result of retiming of the 25 MHz frame pulse which is generated by the ⅛ frequency divider 831 based on the reference clock that is input from the external terminal EXT and distributed to each frame pulse input terminal FP8 of the clock generators 3001, 3002 and 3003 based on the reference clock (which is a signal having the phase that is immediately after being input to the reference clock input terminal REFCLK) in the FF 108.

The multiplication factor of the PLL 920 that generates the low-speed PLL output signal PLLOUTL is 5, the dividing ratio of the ½ frequency-dividing counter 501 in the frequency divider 604 that divides the low-speed PLL output signal PLLOUTL is 2, the dividing ratio of the ¼ frequency-dividing counter 502 therein is 4, the dividing ratio of the ⅛ frequency-dividing counter 503 therein is 8, and the least common multiple of those values is 40. The ratio of the frame pulse FPI8 cycle ( 1/12.5 MHz) to the low-speed PLL output signal PLLOUTL cycle ( 1/500 MHz) is 40, which is the same as the above-mentioned least common multiple of 40.

The multiplication factor of the PLL 920 that generates the high-speed PLL output signal PLLOUTH is 25, the dividing ratio of the ½ frequency-dividing counter 501 in the frequency divider 605 that divides the high-speed PLL output signal PLLOUTH is 2, the dividing ratio of the ¼ frequency-dividing counter 502 therein is 4, and the least common multiple of those values is 100. The ratio of the frame pulse FPI8 cycle ( 1/12.5 MHz) to the high-speed PLL output signal PLLOUTH cycle ( 1/2.5 GHz) is 200, which is a multiple of the above-mentioned least common multiple of 100.

In FIGS. 6A and 6B, DFPL8 indicates the frame pulse differential signal DFPL8 that is output from the synchronous differentiator 704. As a result of synchronous differentiation of the frame pulse FPI8 based on the low-speed PLL output signal PLLOUTL, there is generated the frame pulse differential signal DFPL8, which is a one-shot pulse that has a pulse width corresponding to one cycle of the low-speed PLL output signal PLLOUTL. In FIGS. 6A and 6B, DFPH8 indicates the frame pulse differential signal DFPH8 that is output from the synchronous differentiator 705. As a result of synchronous differentiation of the frame pulse differential signal DFPL8 based on the high-speed PLL output signal PLLOUTH, there is generated the frame pulse differential signal DFPH8, which is a one-shot pulse that has a pulse width corresponding to one cycle of the high-speed PLL output signal PLLOUTH.

In FIGS. 6A and 6B, OL8CLK1, OL8CLK2, OL8CLK4 and OL8CLK8 indicate the 1/1 frequency-divided clock OL8CLK1, the ½ frequency-divided clock OL8CLK2, the ¼ frequency-divided clock OL8CLK4 and the ⅛ frequency-divided clock OL8CLK8, respectively, based on the low-speed PLL output signal PLLOUTL. Because the dividing ratio of the ½ frequency-dividing counter 501 in the frequency divider 604 is 2, the dividing ratio of the ¼ frequency-dividing counter 502 therein is 4, the dividing ratio of the ⅛ frequency-dividing counter 503 therein is 8, and the least common multiple of those values is 8, the determinate state where all of the ½ frequency-divided clock OL8CLK2, the ¼ frequency-divided clock OL8CLK4 and the ⅛ frequency-divided clock OL8CLK8 are “High” (the rising edges 6AH, 6AI and 6AJ) is brought about every 8 cycles of the low-speed PLL output signal PLLOUTL and every 40 cycles of the high-speed PLL output signal PLLOUTH. Specifically, it occurs first time in the REFCLK clock number 1 and the PLLOUTL clock number 3 in FIG. 6A, then in the REFCLK clock number 3 and the PLLOUTL clock number 1 in FIG. 6A. On the other hand, the frame pulse FPI8 and the frame pulse differential signal DFPL8 appear at the cycle of 40 (based on the cycle of the low-speed PLL output signal PLLOUTL) or at the cycle of 200 (based on the cycle of the high-speed PLL output signal PLLOUTH), which is a multiple of the above-described least common multiple 8. Specifically, it occurs first time in the REFCLK clock number 1 and the PLLOUTL clock number 3 or the PLLOUTH clock number 11 in FIG. 6A, then in the REFCLK clock number 9 and the PLLOUTL clock number 3 or the PLLOUTH clock number 11 in FIG. 6B, thereby allowing a series of the above-described synchronization processing. Because the procedure of the series of synchronization processing and the frequency-dividing operation are always triggered only by the rising edge of the low-speed PLL output signal PLLOUTL, a duty cycle of 50% in each frequency-divided clock is assured.

In FIGS. 6A and 6B, OH8CLK1, OH8CLK2 and OH8CLK4 indicate the 1/1 frequency-divided clock OH8CLK1, the ½ frequency-divided clock OH8CLK2 and the ¼ frequency-divided clock OH8CLK4, respectively, based on the high-speed PLL output signal PLLOUTH.

The output of the OR circuit 201 which constitutes the ½ frequency-dividing counter 501 in the frequency divider 605 is determined according to the signal which is fed back from the FF 101 which constitutes the ½ frequency-dividing counter 501 in the frequency divider 605 because the frame pulse differential signal DFPH8 stays “Low” until the REFCLK clock number 1 and the PLLOUTH clock number 6 in FIG. 6A. However, the FF 101 is in the indeterminate state until the REFCLK clock number 1 and the PLLOUTH clock number 7 in FIG. 6A.

On the other hand, in the REFCLK clock number 1 and the PLLOUTH clock number 2 in FIG. 6A, the output of the OR circuit 201, which is the data input to the FF 101, is forcibly fixed to “High” because the frame pulse differential signal DFPH8 is “High”. Thus, at the next rising edge 6AA, the FF 101 of the ½ frequency-dividing counter 501 in the frequency divider 605 fetches (loads) the previous data input at “High”. The FF 101 is thereby initialized to the set state for the first time at this timing, so that the ½ frequency-divided clock OH8CLK2 becomes the determinate state at “High” from the indeterminate state.

After that, at the falling edge 6AB, the frame pulse differential signal DFPH8 returns to “Low”, and thereby the output of the OR circuit 201 in the ½ frequency-dividing counter 501 in the frequency divider 605 returns to the state where it is determined according to the signal which is fed back from the FF 101, which is the state that allows the frequency division.

The output of the OR circuit 201 which constitutes the ¼ frequency-dividing counter 504 in the frequency divider 605 is determined according to the signal which is fed back from the FF 101 which constitutes the ¼ frequency-dividing counter 504 in the frequency divider 605 because the frame pulse differential signal DFPH8 stays “Low” until the REFCLK clock number 1 and the PLLOUTH clock number 6 in FIG. 6A. However, the FF 101 is in the indeterminate state until the REFCLK clock number 1 and the PLLOUTH clock number 7 in FIG. 6A.

On the other hand, in the REFCLK clock number 1 and the PLLOUTH clock number 7 in FIG. 6A, the output of the OR circuit 201, which is the data input to the FF 101, is forcibly fixed to “High” because the frame pulse differential signal DFPH8 is “High”. However, because the FF 101 of the ¼ frequency-dividing counter 504 receives the ½ frequency-divided clock OH8CLK2, which is the output of the ½ frequency-dividing counter 501 in the previous stage, as a clock input and the ½ frequency-divided clock OH8CLK2 is still indeterminate in the REFCLK clock number 1 and the PLLOUTH clock number 8 in FIG. 6A, the FF 101 does not fetch (load) the output of the OR circuit 201 at “High” in the REFCLK clock number 1 and the PLLOUTH clock number 7 in FIG. 6A

Accordingly, in the REFCLK clock number 9 and the PLLOUTH clock number 7 in FIG. 6B when the frame pulse differential signal DFPH8 becomes “High”, the FF 101 of the ¼ frequency-dividing counter 504 is initialized. Thus, the output of the OR circuit 201, which is the data input to the FF 101, is forcibly fixed to “High” in the REFCLK clock number 9 and the PLLOUTH clock number 7 in FIG. 6B.

Thus, at the next rising edge 6BC, the FF 101 of the ¼ frequency-dividing counter 504 in the frequency divider 605 fetches (loads) the previous data input at “High”. The FF 101 is thereby initialized to the set state for the first time at this timing, so that the ¼ frequency-divided clock OH8CLK4 becomes the determinate state at “High” from the indeterminate state. After that, at the falling edge 6BB, the frame pulse differential signal DFPH8 returns to “Low”, and thereby the output of the OR circuit 201 in the ¼ frequency-dividing counter 504 in the frequency divider 605 returns to the state where it is determined according to the signal which is fed back from the FF 101, which is the state that allows the frequency division.

Because the dividing ratio of the ½ frequency-dividing counter 501 in the frequency divider 605 is 2, the dividing ratio of the ¼ frequency-dividing counter 504 therein is 4, and the least common multiple of those values is 4, the determinate state where all of the ½ frequency-divided clock OH8CLK2 and the ¼ frequency-divided clock OH8CLK4 are “High” is brought about every 4 cycles of the high-speed PLL output signal PLLOUTH. Specifically, it occurs first time in the REFCLK clock number 9 and the PLLOUTH clock number 8 in FIG. 6B, then in the REFCLK clock number 9 and the PLLOUTH clock number 12 in FIG. 6B, and further in the REFCLK clock number 9 and the PLLOUTH clock number 16 in FIG. 6B. On the other hand, the frame pulse FPI8 and the frame pulse differential signal DFPH8 appear at the cycle of 200 (based on the cycle of the high-speed PLL output signal PLLOUTH), which is a multiple of the above-described least common multiple 4. Specifically, it occurs first time in the REFCLK clock number 9 and the PLLOUTH clock number 8 in FIG. 6B, then in the REFCLK clock number 17 and the PLLOUTH clock number 8 though not shown, thereby allowing a series of the above-described synchronization processing. Because the procedure of the series of synchronization processing and the frequency-dividing operation are always triggered only by the rising edge of the high-speed PLL output signal PLLOUTH, a duty cycle of 50% in each frequency-divided clock is assured.

### Fourth Embodiment

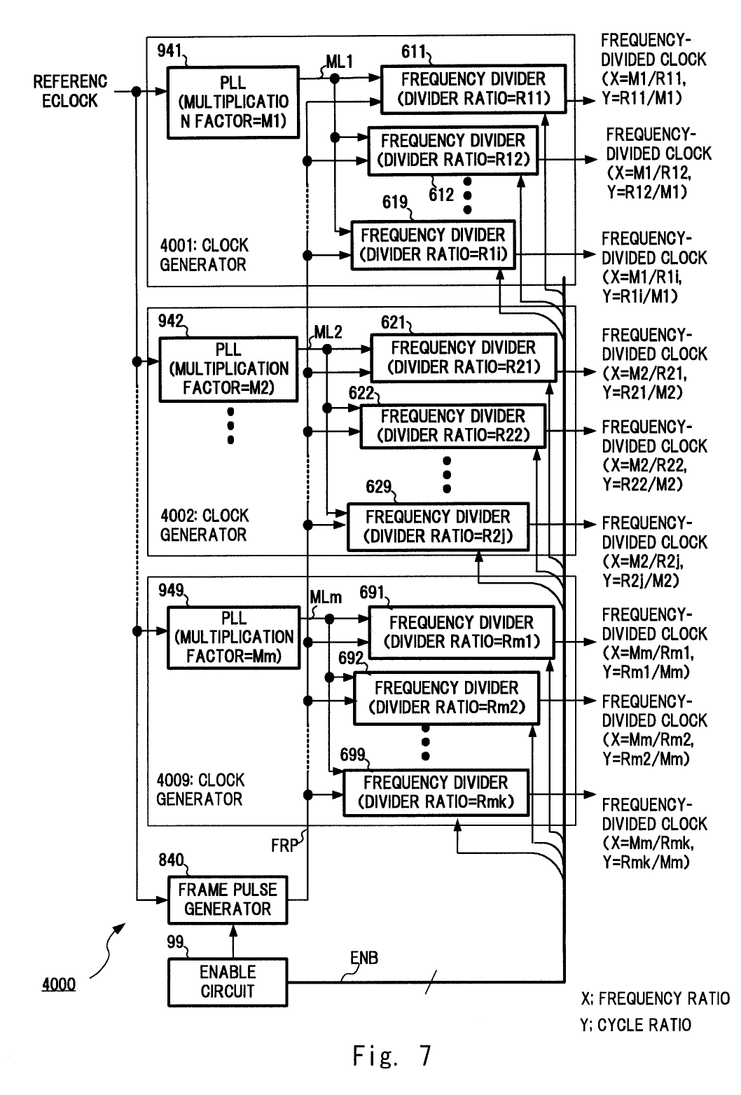

FIG. 7 shows a clock synchronization system 4000 according to a fourth embodiment of the present invention. The clock synchronization system 4000 includes a total m number (m is a natural number) of clock generators 4001, 4002 to 4009, a frame pulse generator 840, and an enable circuit 99.

The clock generator 4001 is described hereinafter in detail. The clock generator 4001 includes a PLL 941 that has a multiplication function with a multiplication factor M1, and a total i number (i is a natural number) of frequency dividers 611, 612 to 619 that have a frequency division function with dividing ratios R11, R12 to R1i, respectively. The PLL 941 receives the reference clock, multiplies the reference clock by the multiplication factor M1, and outputs a phase-locked clock signal ML1. The phase-locked clock signal ML1 is distributed to each frequency divider. The frequency dividers 611, 612 to 619 receive the phase-locked clock signal ML1, divides the phase-locked clock signal ML1 by the dividing ratios R11, R12 to Rli, respectively, and output frequency-divided clocks. Consequently, the frequency-divided clocks which are output from the frequency dividers 611, 612 to 619 have frequency ratios of M1/R11, M1/R12 to M1/R1i, respectively, to the reference clock.

The clock generators 4002 to 4009 have the same circuit configuration as the clock generator 4001. In the clock generators 4002 to 4009, PLLs 942 to 949 respectively have multiplication factors M2 to Mm, and the frequency dividers 621, 622 to 629 and the frequency dividers 691, 692 to 699 respectively have the dividing ratios R21, R22 to R2j (j is a natural number) and the dividing ratios Rm1, Rm2 to Rmk (k is a natural number). The PLLs 942 to 949 receive the reference clock, multiply the reference clock by each multiplication factor, and output phase-locked clock signals ML2 to MLm. The phase-locked clock signals ML2 to MLm are distributed to each frequency divider. The frequency dividers 621, 622 to 629 and 691, 692 to 699 receive the phase-locked clock signals and output frequency-divided clocks. Consequently, the frequency-divided clocks which are output from the frequency dividers 621, 622 to 629 and 691, 692 to 699 have frequency ratios of M2/R21, M2/R22 to M2/R2j, and Mm/Rm1, Mm/Rm2 to Mm/Rmk, respectively, to the reference clock.

The enable circuit 99 outputs an enable signal ENB that determines whether to activate each frequency divider. The enable circuit 99 may have a function to generate the enable signal ENB according to an external instruction, or a function to generate the enable signal ENB according to a result of observing the whole system to which the clock synchronization system 4000 is applied. As an example of the latter case, when the clock synchronization system 4000 is applied to an LSI chip, a clock domain where a frequency-divided clock is distributed may be temporarily stopped as a result of system operation. In order to reduce power consumption of the clock domain in the temporary stop state, a specific frequency divider which serves as a clock tree distributor or a clock supply source in each clock domain also needs to enter the temporary stop state. Thus, the enable circuit 99 generates the enable signal ENB for causing the specific frequency divider, which is one selected from the frequency dividers 611 to 619, 621 to 629 and 691 to 699, to enter the temporary stop state.

The frame pulse generator 840 receives the reference clock and outputs the frame pulse FRP. The cycle of the frame pulse FRP is the cycle ratio of the frequency-divided clock to the reference clock, which is the value of a common multiple and a natural number. The cycle ratio of the frame pulse FRP to the reference clock in the clock synchronization system 4000 is calculated by the following expression 1:

A frame pulse cycle ratio (to a reference clock cycle)=n*LCM {1. IF “611”=enable, R11/M1, 1},
IF “612”=enable, R12/M1, 1}, . . .
IF “619”=enable, Rli/M1, 1},
IF “621”=enable, R21/M2, 1},
IF “622”=enable, R22/M2, 1}, . . .
IF “629”=enable, R2j/M2, 1}, . . .
IF “691”=enable, Rm1/Mm, 1},
IF “692”=enable, Rm2/Mm, 1}, . . .
IF “699”=enable, Rmk/Mm, 1}

In the above expression, n indicates a natural number, and LCM indicates a function to calculate a least common multiple. For example, “IF{“611”=enable, R11/M1, 1}” indicates the function that has the value “R11/M1” when the frequency divider 611 is in the enabled or active state and has the value “1” when the frequency divider 611 is in the disabled or inactive state. The cycle of the frame pulse FRP is calculated by implementing each of the above-described functions of IF-statement on all the frequency dividers 611 to 619, 621 to 629 and 691 to 699, calculating the least common multiple of each obtained value and a natural number 1, and multiplying the result by n. The enable circuit 99 notifies the frame pulse generator 840 of the information about which of the frequency dividers 611 to 619, 621 to 629 and 691 to 699 is in the enabled state.

The frequency dividers 611 to 619, 621 to 629 and 691 to 699 are implemented by units that make synchronization according to the frame pulse FRP, such as the circuits described in the first, the second and the third embodiments, for example. The frequency dividers are, however, not limited to the circuits described in the first, the second and the third embodiments, and various changes may be made without departing from the scope of the present invention.

The expression 1 may be applied to the clock synchronization system 1000 shown in FIG. 1 as follows. Because the clock generators 1002 and 1003 have the same configuration as the clock generator 1001, the clock generator 1001 is described hereinafter on behalf of the clock generators.

Conditions are: m=1, i=3, M1=4, R11=2, R12=4 and R13=8, and each frequency divider is in the enabled state. Accordingly, the expression 1 is expressed as:

n*LCM(1, 2/4,4/4, 8/4)

After the reduction to common denominator, it is expressed as:

n*LCM(4/4, 2/4,4/4, 8/4)

Calculation of the least common multiple of the numerators results in:

n*2

The clock generator 1001 substitutes n=2 and thereby generates the frame pulse FP which has four times the cycle (one-fourth the frequency) of the reference clock that is input to the external terminal EXT.

The expression 1 may be applied to the clock synchronization system 2000 shown in FIG. 3 as follows. Because the clock generators 2002 and 2003 have the same configuration as the clock generator 2001, the clock generator 2001 is described hereinafter on behalf of the clock generators.

Conditions are: m=2, i=2, j=2, M1=25, R11=2, R12=4, M2=5, R21=2 and R22=4, and each frequency divider is in the enabled state. Accordingly, the expression 1 is expressed as:

n*LCM(1, 2/25, 4/25,⅖,⅘)

After the reduction to common denominator, it is expressed as:

n*LCM(25/25, 2/25, 4/25, 10/25, 20/25)

Calculation of the least common multiple of the numerators results in:

n*4

The clock generator 2001 substitutes n=1 and thereby generates the frame pulse FP4 which has four times the cycle (one-fourth the frequency) of the reference clock that is input to the external terminal EXT.

The expression 1 may be applied to the clock synchronization system 3000 shown in FIG. 5 as follows. Because the clock generators 3002 and 3003 have the same configuration as the clock generator 3001, the clock generator 3001 is described hereinafter on behalf of the clock generators.

Conditions are: m=2, i=2, j=3, M1=25, R11=2, R12=4, M2=5, R21=2 R22=4 and R23=8, and each frequency divider is in the enabled state. Accordingly, the expression 1 is expressed as:

n*LCM(1, 2/25, 4/25,⅖,⅘, 8/5)

After the reduction to common denominator, it is expressed as:

n*LCM(25/25, 2/25, 4/25, 10/25, 20/25, 40/25)

Calculation of the least common multiple of the numerators results in:

n*8

The clock generator 3001 substitutes n=1 and thereby generates the frame pulse FP8 which has eight times the cycle (one-eighth the frequency) of the reference clock that is input to the external terminal EXT.

As described in the foregoing, in the embodiment of the clock synchronization system which includes the phase-locked loop that generates a multiplied clock based on the reference clock, the frequency divider that generates frequency-divided clocks based on the multiplied clock, and the frame pulse generator that generates a frame pulse from the reference clock, and further includes a unit that makes synchronization according to the frame pulse, the clock synchronization systems shown in FIGS. 1, 3, 5 and 7 have common features.

### Other Embodiments

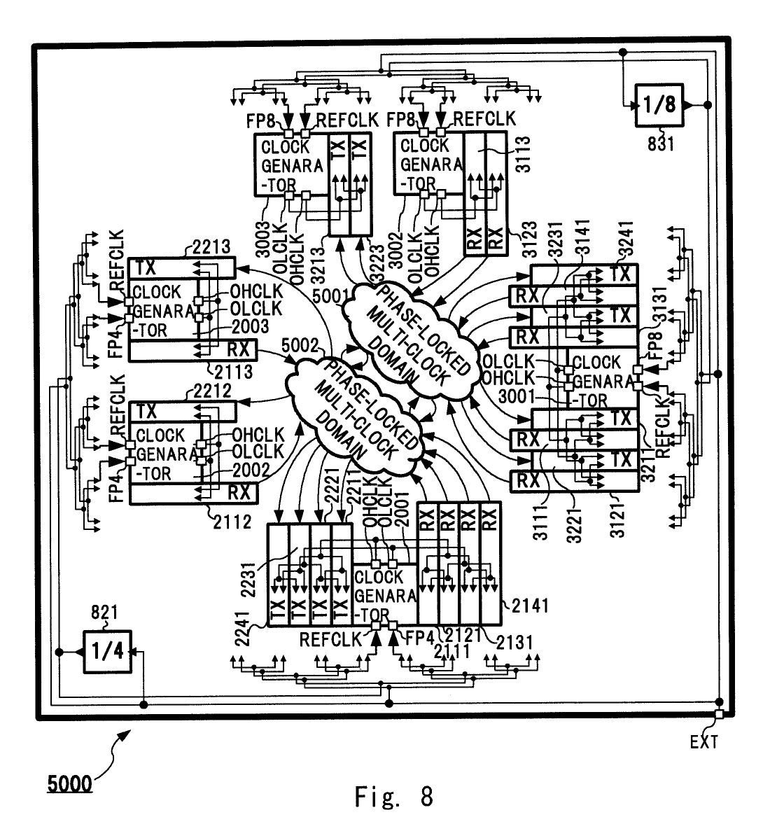

The present invention is not restricted to the above-described embodiments, and various changes and modifications may be made without departing from the scope of the invention. FIG. 8 shows an LSI chip 5000. Specifically, FIG. 8 shows the overall configuration of a data transmission system in which the clock synchronization system 2000 shown in FIG. 3 and the clock synchronization system 3000 shown in FIG. 5 are disposed on an LSI chip 5000. Although the LSI chip 5000 is described hereinafter in detail with reference to FIG. 8, the elements and symbols which are shown in FIGS. 3 and 5 are not described in detail herein.

Multi-clock domains 5001 and 5002 are a plurality of clock domains that define the range of a circuit to operate with one clock. Transceivers (“TX” described in FIG. 8) 3211, 3221, 3231 and 3241 convert parallel data that is supplied from the multi-clock domain 5001 into serial data and output the serial data to the outside of the LSI chip. Receivers (“RX” described in FIG. 8) 3111, 3121, 3131 and 3141 convert serial data that is supplied from the outside of the LSI chip into parallel data and output the parallel data to the multi-clock domain 5001.

The clock generator 3001 is disposed on the right side of the LSI chip 5000. Further, transceivers 3211 and 3221 and receivers 3111 and 3121 are alternately arranged adjacent to each other on the left side toward the center of the chip, and transceivers 3231 and 3241 and the receivers 3131 and 3141 are alternately arranged adjacent to each other on the right side toward the center of the chip, thereby constituting an integral serializer/deserializer (SERDES) macro having four channels of transceivers and four channels of receivers.

Synchronous clocks that are output from the synchronous clock output terminals OLCLK and OHCLK of the clock generator 3001 are distributed with an equal delay as a transmitting/receiving clock source to each TX and RX through tree-like lines including a repeater buffer inserted therein as shown in FIG. 8. Each TX and RX can select a transmitting/receiving clock from the synchronous clock output terminals OLCLK and OHCLK. Further, the synchronous clock which is output from the synchronous clock output terminal OLCLK can be selected from the 1/1 frequency-divided clock OL8CLK1, the ½ frequency-divided clock OL8CLK2, the ¼ frequency-divided clock OL8CLK4 and the ⅛ frequency-divided clock OL8CLK8 by the selector MUX4. Likewise, the synchronous clock which is output from the synchronous clock output terminal OHCLK can be selected from the 1/1 frequency-divided clock OH8CLK1, the ½ frequency-divided clock OH8CLK2 and the ¼ frequency-divided clock OH8CLK4 by the selector MUX5.

The 1/1 frequency-divided clock OL8CLK1, the ½ frequency-divided clock OL8CLK2, the ¼ frequency-divided clock OL8CLK4 and the ⅛ frequency-divided clock OL8CLK8, and the 1/1 frequency-divided clock OH8CLK1, the ½ frequency-divided clock OH8CLK2 and the ¼ frequency-divided clock OH8CLK4 are determinately phase-locked with each other. In other words, those frequency-divided clocks are in the determinate initial state that triggers the restart of the frequency dividing operation, or in the relationship in which their signal transitions are mutually determined. Therefore, the serial data that is output from TX to the outside of the LSI chip is mutually phase-locked among the channels of the transceivers 3211, 3221, 3231 and 3241. The parallel data that is output from RX to the multi-clock domain 5001 is also mutually phase-locked among the channels of the receivers 3111, 3121, 3131 and 3141.

The clock generator 3002 is disposed on the upper side of the LSI chip 5000, and receivers 3113 and 3123 are arranged adjacent to each other only on the left side toward the center of the chip, thereby constituting an integral SERDES macro having two channels of receivers. The clock generator 3003 is disposed on the upper side of the LSI chip 5000, and transceivers 3213 and 3223 are arranged adjacent to each other only on the left side toward the center of the chip, thereby constituting an integral SERDES macro having two channels of transceivers. Furthermore, the serial data that is output from TX to the outside of the LSI chip is mutually phase-locked between the channels of the transceivers 3213 and 3223. The parallel data that is output from RX to the multi-clock domain 5001 is also mutually phase-locked between the channels of the receivers 3113 and 3123.

From the external terminal EXT at the lower right corner of the LSI chip 5000 to each reference clock input terminal REFCLK of the clock generators 3001, 3002 and 3003, clocks are distributed with an equal delay through tree-like lines including a repeater buffer inserted therein as shown in FIG. 8. Further, the ⅛ frequency divider 831 at the upper right corner of the LSI chip 5000 receives the reference clock from the external terminal EXT as an input and distributes the clock with an equal delay from the output terminal to each frame pulse input terminal FP8 of the clock generators 3001, 3002 and 3003 through tree-like lines including a repeater buffer inserted therein as shown in FIG. 8.

The reference clocks that are input to the reference clock input terminals REFCLK and the frame pulses that are input to the frame pulse input terminals FP8 of the clock generators 3001, 3002 and 3003 are in the relationship that has a zero skew. Therefore, the signals at the synchronous clock output terminals OLCLK and OHCLK of the clock generators 3001, 3002 and 3003 are also mutually phase-locked, and the serial data that is output from TX to the outside of the LSI chip is mutually phase-locked among the channels of the transceivers 3211, 3221, 3231, 3241, 3213 and 3223. The parallel data that is output from RX to the multi-clock domain 5001 is also mutually phase-locked among the channels of the receivers 3111, 3121, 3131, 3141, 3113 and 3123.

The reference clock that is input to the external terminal EXT and the frame pulse that is generated by the ⅛ frequency divider 831 which are distributed in common to the clock generators 3001, 3002 and 3003 have a lower frequency than the frequency-undivided clocks PLLOUTH and PLLOUTL having a high frequency (which are a high-speed PLL output signal and a low-speed PLL output signal that are generated by the PLL 920 in each of the clock generators 3001, 3002 and 3003). Therefore, when the clock synchronization system is applied to a large-scale, high-integration, high-density LSI chip as in this embodiment, even if the reference clock and the frame pulse are distributed all over the LSI chip through a long distance line, the signal integrity of those signals is still assured. Stated differently, it is possible to build the clock synchronization system all over the LSI chip without degrading the signal integrity.

The clock generator 2001 is disposed on the lower side of the LSI chip 5000. Further, transceivers 2211, 2221, 2231 and 2241 are arranged adjacent to each other on the left side toward the center of the chip, and receivers 2111, 2121, 2131 and 2141 are arranged adjacent to each other on the right side toward the center of the chip, thereby constituting an integral SERDES macro having four channels of transceivers and four channels of receivers. The clock generator 2002 is disposed on the left side of the LSI chip 5000. Further, a transceiver 2212 is arranged on the left side toward the center of the chip, and a receiver 2112 is arranged on the right side toward the center of the chip, thereby constituting an integral SERDES macro having one channel of transceiver and one channel of receiver. The clock generator 2003 is disposed on the left side of the LSI chip 5000. Further, a transceiver 2213 is arranged on the left side toward the center of the chip, and a receiver 2113 is arranged on the right side toward the center of the chip, thereby constituting an integral SERDES macro having one channel of transceiver and one channel of receiver.

From the external terminal EXT at the lower right corner of the LSI chip 5000 to each reference clock input terminal REFCLK of the clock generators 2001, 2002 and 2003, clocks are distributed with an equal delay through tree-like lines including a repeater buffer inserted therein as shown in FIG. 8. Further, the ¼ frequency divider 821 at the lower left corner of the LSI chip 5000 receives the reference clock from the external terminal EXT as an input and distributes with an equal delay the clock from the output terminal to each frame pulse input terminal FP4 of the clock generators 2001, 2002 and 2003 through tree-like lines including a repeater buffer inserted therein as shown in FIG. 8.

Consequently, the signals at the synchronous clock output terminals OLCLK and OHCLK of the clock generators 2001, 2002 and 2003 are also mutually phase-locked, and the serial data that is output from TX to the outside of the LSI chip is mutually phase-locked among the channels of the transceivers 2211, 2221, 2231, 2241, 2212 and 2213. The parallel data that is output from RX to the multi-clock domain 5002 is also mutually phase-locked among the channels of the receivers 2111, 2121, 2131, 2141, 2112 and 2113.

The SERDES shown in FIG. 8 is described assuming the most classic technique of source synchronous clocking, in which a transmitting end transmits data and a timing clock in the synchronous transmission. In this system, a timing clock that is sent from the transmitting end is applied to the above-described reference clock.

A recent SERDES receiver generally includes a clock data recovery circuit because the effect of a clock delay (skew) or jitter becomes larger to affect the data transmission with an increase in the distance of transmission and the speed of clocks. A clock data recovery is a technique of embedding clock information in transmitted data itself so as to allow accurate data reading in spite of an arrival time interval between data line paths. The technique retrieves or reproduces the clock information from the data and reads the transmitted data based on the clock.

In the receiver with the clock data recovery, there is no need to distribute OLCLK or OHCLK with an equal delay. If the receiver including the clock data recovery circuit is applied to the above-described LSI chip 5000, the parallel data that is synchronous with the clock which is reproduced by the clock data recovery needs to be in-phase with the clock that drives the multi-clock domain (5001 or 5002). Therefore, the receiver further includes an elastic buffer to perform clock transfer for synchronizing the parallel data and the clock for driving the multi-clock domain. As the elastic buffer, a small-capacity first-in first-out (FIFO) register in which a reading/writing pointer changes dynamically may be used.

On the other hand, the transceiver includes an alignment buffer, which is a circuit equivalent to the elastic buffer in the receiver. The alignment buffer performs clock transfer for synchronizing the parallel data that is synchronous with the clock for driving the multi-clock domain (5001 or 5002) and the clock in the receiver (OLCLK or OHCLK).

It is apparent that the present invention is not limited to the above embodiment, but may be modified and changed without departing from the scope and spirit of the invention.

What is claimed is:

1. A clock synchronization system comprising:
a phase synchronization circuit to generate a multiplied clock based on a reference clock;
a frequency divider to generate a plurality of frequency-divided clocks based on the multiplied clock; and
a frame pulse generator to generate a frame pulse by frequency-dividing the reference clock, wherein
the frequency-divided clocks are phase-locked by the frame pulse.

2. The clock synchronization system according to claim 1, wherein
a cycle ratio of the frame pulse to the reference clock is a natural number and a common multiple of clock ratios of the plurality of frequency-divided clocks to the reference clock.

3. The clock synchronization system according to claim 2, wherein
the cycle ratio of the frame pulse is minimum.

4. The clock synchronization system according to claim 1, wherein
a pulse width of the frame pulse is equal to or larger than a pulse width of the reference clock.

5. The clock synchronization system according to claim 4, wherein
the pulse width of the frame pulse has a duty cycle of 50%.

6. The clock synchronization system according to claim 1, wherein
the frequency divider includes:
a synchronous differentiator to generate a synchronous differential signal having a cycle of the frame pulse and a pulse width corresponding to one cycle of the multiplied clock; and
a frequency-dividing counter to load the synchronous differential signal for initialization with the multiplied clock acting as a trigger.

7. A clock synchronization system comprising:
a first phase synchronization circuit to generate a first multiplied clock based on a reference clock;
a second phase synchronization circuit to generate a second multiplied clock based on the reference clock;
a first frequency divider to generate a first frequency-divided clock based on the first multiplied clock;
a second frequency divider to generate a second frequency-divided clock based on the second multiplied clock; and
a frame pulse generator to generate a frame pulse by frequency-dividing the reference clock, wherein
the first frequency-divided clock and the second frequency-divided clock are phase-locked by the frame pulse.

8. The clock synchronization system according to claim 7, wherein
a cycle ratio of the frame pulse to the reference clock is a natural number and a common multiple of clock ratios of the first frequency-divided clock and the second frequency-divided clock to the reference clock.

9. The clock synchronization system according to claim 8, wherein
the cycle ratio of the frame pulse is minimum.

10. The clock synchronization system according to claim 7, wherein
a pulse width of the frame pulse is equal to or larger than a pulse width of the reference clock.

11. The clock synchronization system according to claim 10, wherein
the pulse width of the frame pulse has a duty cycle of 50%.

12. The clock synchronization system according to claim 7, wherein
the first frequency divider includes:
a first synchronous differentiator to generate a first synchronous differential signal having a cycle of the frame pulse and a pulse width corresponding to one cycle of the first multiplied clock; and
a first frequency-dividing counter to load the first synchronous differential signal for initialization with the first multiplied clock acting as a trigger, and
the second frequency divider includes:
a second synchronous differentiator to generate a second synchronous differential signal having a cycle of the frame pulse and a pulse width corresponding to one cycle of the second multiplied clock; and
a second frequency-dividing counter to load the second synchronous differential signal for initialization with the second multiplied clock acting as a trigger.

13. The clock synchronization system according to claim 7, wherein
the first phase synchronization circuit and the second phase synchronization circuit have different multiplication factors from each other.

14. The clock synchronization system according to claim 7, wherein
the first frequency-divided clock and the second frequency-divided clock have different cycles from each other.

15. The clock synchronization system according to claim 7, wherein
the reference clock is distributed to the first frequency divider and the second frequency divider with an equal delay, and
the frame pulse is distributed to the first frequency divider and the second frequency divider with an equal delay.

16. A semiconductor integrated circuit, wherein
the clock synchronization system according to claim 1 is formed on one semiconductor substrate.
